(19) United States
(12) Patent Application Publication
(10) Pub. No.: US 2005/0146319 A1
(43) Pub. Date: Jul. 7, 2005

(54) Live Dead Live - Voltmeter Operability Tester

(75) Inventor: Warren Alfred Weems II, Avondale, AZ (US)

Correspondence Address: MARK F. WRIGHT;WRIGHT LAW GROUP, PLLC, 7201 WEST OAKLAND, SUITE 2, CHAUDLER, AZ, 85226, US

(73) Assignee: WMW GROUP LLC, Avondale, AZ (US)

(21) Appl. No.: 10/707,635

(22) Filed: Dec. 29, 2003

(51) Int. Cl. G01R 1/00

(52) U.S. Cl. 324/158.1

(57) ABSTRACT

Methods and apparatus for performing a “safe working practice” known as a live-dead-live test on a voltmeter to confirm that the meter is operational before being relied upon to verify an electrical circuit, component, device and/or equipment is de-energized. The live-dead-live tester is transported to the location at which the voltmeter will be used to verify an electrical circuit, component, device and/or equipment is de-energized. The voltmeter is set to read either AC or DC voltage. The voltage selection switch on the live-dead-live tester is then moved from the “off” position to the position that will output the same type of voltage that the voltmeter is set to indicate. The LED for the type of voltage selected on the LDL will then illuminate, indicating that the LDL battery is good and that it is supplying the output selected. The voltmeter operability will then be verified. If the voltmeter is operable and its indication is correct the test probes, test leads and sensing and display circuits have now been verified to be intact. The voltmeter can now be used to verify the circuit under test is de-energized. After the circuit has been verified de-energized and prior to starting work the voltmeter is once again tested using the same method described above to verify that the meter did not fail during the circuit testing process.

### BACKGROUND OF INVENTION

1. Field of the Invention

The present invention relates generally to the verification that a voltmeter and its test probes, test leads and sensing and display circuits are working and more particularly to an improved method and apparatus to verify a voltmeter and its test probes, test leads and sensing and display circuits are working before and after each use.

2. Background and Related Art

Voltage is a term used to describe the amount of energy or electromotive force available to move a certain amount of electrons from one point to another in an electrical circuit, which results in a difference in electrical potential between two points. A conductor is a substance or object that offers a pathway for electrons or current to flow. Resistance is a term that describes an inhibitor of electron or current flow. Current and resistance are inversely proportional in that the higher the resistance the lower the current flow. When voltage or electrical pressure is exerted upon a conductive closed loop or circuit, current will flow within the circuit and if voltage is applied to an open circuit no current will flow; however, both circuits are said to be energized.

Voltage can be represented by two typical forms, alternating current (AC) or direct current (DC) voltage, both forms are commonly used to supply various electrical circuits and electrical equipment. A voltmeter is an instrument used to determine whether or not there is a difference in electrical potential between two points and if there is a difference in potential, to determine the magnitude of the difference in potential. A voltmeter is a very high resistance device so that very little current flows when a voltage measurement is being taken and therefore it consumes very little power.

A voltage indication seen on the meter signifies that there is a difference in potential between the two points being measured. Two or more conductors, with an earthen or equipment ground considered as a conductor, having such a difference, are considered to be energized. Thus a voltmeter is utilized to determine whether or not a circuit is energized or de-energized.

A voltmeter that does not indicate properly can lead a user to believe that a circuit is de-energized when in fact the circuit is energized. This can lead to many hazards with varying consequences, ranging from very minor to disastrous including damage to electrical equipment, shocks and burns or even death to the user of the faulty voltmeter as well as his/her co-workers.

In an attempt to avoid the preceding hazards the Occupational Safety & Health Administration (OSHA) has adopted certain regulations (Standards 29 CFR) under which “Selection And Use Of Work Practices 1910.333” has been incorporated. Under paragraph 1910.333(b)(2)(iv)(B) it states: “A qualified person shall use test equipment to test the circuit elements and electrical parts of equipment to which employees will be exposed and shall verify that the circuit elements and equipment parts are de-energized. The test shall also determine if any energized condition exists as a result of inadvertently induced voltage or un-related voltage back-feed even though specific parts of the circuit have been de-energized and presumed to be safe. If the circuit to be tested is over 600 volts, nominal, the test equipment shall be checked for proper operation immediately after this test.”

A voltmeter is commonly the test equipment of choice used to test the circuit elements and electrical parts of the circuit to verify that they are de-energized. Even though the OSHA guidelines specifically point out that the test equipment used to verify voltages above 600 volts shall be checked for proper operation immediately after testing for energized circuits has occurred, many companies have adopted this ideology for all voltages. Before working on a circuit, a common “safe working practice” is to check the voltmeter on a known energized voltage source to verify that the meter is operational. These checks also verify that the voltmeter's test probes and test leads are functional. The voltmeter is then used to check and verify whether or not the circuit and/or equipment to be worked on is de-energized and as a last check to verify the meter did not fail during the circuit testing, the meter is again checked against the known energized voltage source. This testing is commonly referred to as a live-dead-live (LDL) check.

Currently the technique for performing a live-dead-live check of a voltage meter requires the user to locate a known energized source of potential and verify the meter is operating properly. The user would then check the circuit to be worked on to verify it is de-energized, as evidenced by no voltage indication on the meter. Finally, before starting work on the circuit/equipment, the user would once again verify that the meter is operating properly by re-checking the meter against the known energized source. If the meter operates properly during the final check against the known energized source, then the user would know that the meter had not suffered a failure before or after the circuit/equipment to be worked on was verified to be de-energized or “dead”.

Known techniques/methods of performing a live-dead-live check of a voltmeter can be very time consuming and may provide a false sense of security to the user if there is an intermittent problem with the meter or its test leads. Also, in some cases both AC and DC voltage may need to be verified depending upon the type of circuit or equipment on which the work is going to be performed. Typically the user will first test the meter on a known energized source to verify the meter is operating properly. The user will then take the voltmeter to the location where the work is to be performed and verify the circuit/equipment is de-energized. Finally, the user will return to the known energized source and re-verify the meter is operating properly. If the circuit/equipment to be worked on is located in an area where a known source is not present, the user must leave the area to verify the meter is operating properly. If both AC and DC voltages are present in the circuit/equipment to be worked on this process may have to be repeated twice, so that the user can verify that the meter is operating properly for both types of voltage. This technique/methodology is obviously inconvenient and time consuming and could lead to the user to deciding not to perform the live-dead-live checks. This decision could lead to dire consequences as the un-verified meter then becomes the sole barrier in preventing personnel injury and/or equipment damage.

In addition to the inconvenience, theoretically the meter could pass all the live-dead-live checks but due to an intermittent problem that presents itself while moving from the location where the initial meter verification was performed to the work location, it could still indicate the circuit/equipment is de-energized when in fact it is energized. The user may attempt to minimize the possibility of an intermittent problem going un-noticed and presenting itself after the initial meter verification by bringing a portable voltage source to the work area to perform the live-dead-live checks. This requires the user to carry a portable AC and/or DC source, which is often large and heavy, and an extension cord to the work area. He must also locate a reliable power source to feed the portable unit to avoid inaccurate results while performing the live-dead-live checks. In addition, many industrial and commercial facilities utilize circuits and/or equipment that are located in harsh environments. Normally, in instances where the work will be performed in a harsh environment, every effort is made to minimize the amount of test equipment taken into the work area for safety and environmental reasons.

Thus, while techniques currently exist to perform live-dead-live tests on voltmeters, challenges still exist. Accordingly, it would be an improvement in the art to augment or even replace the current techniques with new techniques.

### SUMMARY OF INVENTION

The overall objective of the present invention is to provide a new method for performing live-dead-live checks or tests on a voltmeter. More particularly, a further objective of the present invention is to provide an improved method to perform live-dead-live checks or tests in which a single, simple, reliable, small, self contained, portable, battery powered device is utilized to perform live-dead-live checks for voltmeters designed to measure AC and/or DC voltages.

Accordingly, the present invention takes advantage of known standard electronic circuits to provide a portable “voltage indication” meter validation tester. The invention consists of three main components, an AC voltage output, a DC voltage output and LED's, used for indication. An illuminated LED indicates that the output is energized. The tester may be built into a small portable case or enclosure or the three components may be built into other existing devices, such as a flashlight or a voltmeter.

Implementation of the present invention enables a voltmeter user to utilize a light weight, small, portable tester that can be kept in the meter user's possession and in close proximity to the circuit and/or equipment to be worked on, without the need for cords or a power supply.

Accordingly, with the art described herein, a voltmeter user can verify locally, without inconvenience, that the voltmeter to be used to measure the circuit and/or equipment voltage potential is operational. The meter user will carry the portable LDL tester with the meter to the circuit to be worked on. The meter user will then choose the type of voltage, either AC or DC, that will be measured with the voltmeter. An indicating LED will let the voltmeter user know that the portable LDL tester has sufficient battery power and output power for the type of voltage chosen. The meter user will then insert the probes of the voltmeter into the output jacks provided on the LDL tester. If the voltmeter is operational, an appropriate reading will be displayed on the voltmeter for the type of voltage selected on the LDL tester. This will indicate that the test leads, the voltmeter sensing circuit and the voltmeter display are operational. The voltmeter user can then verify that the circuit/equipment to be worked on is de-energized. After the voltage checks are completed, the meter user will again insert the meter probes into the LDL tester's output jacks and verify that the voltmeter is operational, indicating the circuit/equipment to be worked on is truly de-energized.

Furthermore, implementation of the present invention assists making the live-dead-live testing an easily performed function and an easily ingrained “safe working practice” for all voltmeter users, thereby preventing or minimizing the possibility of personnel injury and/or equipment damage.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF DRAWINGS

In order that the manner in which the above recited and other features and advantages of the present invention are obtained, a more particular description of the invention will be rendered by reference to specific embodiments thereof, which are illustrated in the appended drawings. Understanding that the drawings depict only typical embodiments of the present invention and are not, therefore, to be considered as limiting the scope of the invention, the present invention will be described and explained with additional specificity and detail through the use of the accompanying drawings in which:

FIG. 1 illustrates a three dimensional diagram of the present invention.

FIG. 2 illustrates the present invention connected to a “typical” voltmeter

### DETAILED DESCRIPTION

The present invention relates to a method or methods and an apparatus used to perform live-dead-live tests on a voltmeter. More particularly, the present invention relates to a method and an apparatus that confirms the voltmeter is operational before relying on its indication prior to performing work on an electrical circuit, electrical equipment or devices or components of an electrical circuit.

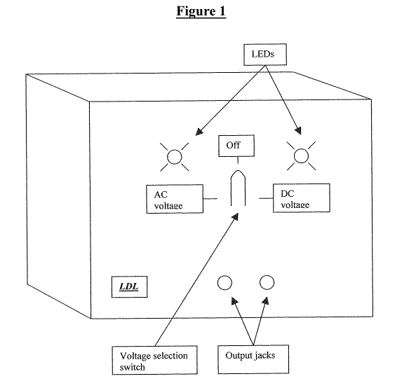

Some embodiments of the present invention enable an initial “live” check of a voltmeter's indication to be performed using an apparatus that can be relied upon to be functional, thereby the meter user can be confident that the meter is operational. The apparatus will have both AC and DC voltage output capability. The meter user will select the type of output voltage desired by the “voltage selection switch” on the apparatus (see FIG. 1) depending on the type of circuit voltage the voltmeter will be used to measure.

Some embodiments further embrace using light emitting diode (LED) indications connected to the AC and DC output jacks of the apparatus, henceforth referred to as the “LDL” tester. With the “voltage selection switch” in the “off” position there will be no LED indication, in the AC position the corresponding LED will illuminate and in the DC position the corresponding LED will illuminate. Both LED's are fed from the output of their corresponding voltage chosen from the “voltage selection switch”. Therefore the user will be confident that when either AC or DC voltage is selected and its corresponding LED is illuminated, the LDL tester is working properly.

Still further embodiments of the present invention enable the LDL tester to be fed from a small battery. Since the voltmeter is a high resistance device, very little power is required to operate the voltage indication of the meter. Therefore, the LDL tester only uses a small battery to power all of it's circuitry. The LED indications of the LDL tester also serve to let the meter user know when the battery has exceeded its useful life. No LED illumination when the voltage selection switch is moved to AC or DC from the off position would indicate to the user that either the battery doesn't have sufficient power or a failure has occurred within the LDL tester circuitry.

Still further embodiments of the present invention enable the LDL tester to be very light weight and portable. Since the LDL tester uses a small battery and standard electronic circuitry to provide either an AC or DC output, portability is achieved.

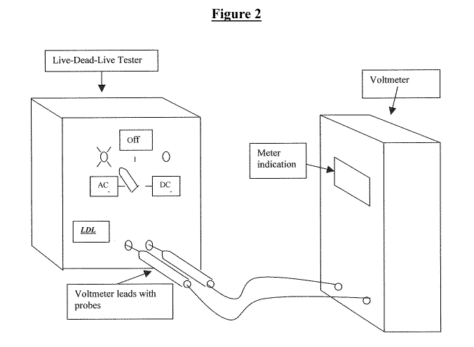

Accordingly, those skilled in the art will appreciate the methods, processes and features discussed herein relating to the embodiments of the present invention. The LDL tester will allow a live-dead-live test of a voltmeter to be performed prior to using the voltmeter to confirm that an electrical circuit, components of a circuit, and/or electrical equipment are de-energized. The LDL tester allows a voltmeter user the flexibility to transport the portable LDL tester to the circuit or equipment that will be checked by the voltmeter user. The user will then put the voltmeter on the proper scale for the circuit or equipment voltage the meter will be used to check. Then, as shown in FIG. 2, the appropriate type of voltage will be selected on the LDL tester and the appropriate LED will illuminate indicating that the output is correct and that the LDL battery has sufficient power.

Those skilled in the art will also appreciate that the voltmeter probes can then be inserted into the output jacks of the LDL tester and the voltmeter indication can be verified to be operational. If the voltmeter cannot be verified to be operational, utilizing the LDL test, the meter should not be used to confirm a circuit, components, devices and/or equipment are de-energized. If the voltmeter is verified to be operational utilizing the LDL tester it can then be utilized to verify that the circuit to be worked on is de-energized. If voltage is indicated, the circuit under test should be de-energized and re-verified utilizing the LDL tester and the voltmeter in accordance with the methods described herein. If the circuit under test is not energized, the voltmeter should be re-tested with the LDL tester to verify that it is still operational and did not fail while the voltage checks were being made.

The LDL tester is the only battery powered, portable, lightweight test apparatus available that may be relied upon to perform a live-dead-live test on a voltmeter. Accordingly, it is highly desirable to the utility, mining, manufacturing, and various other industries worldwide that are adopting the safe working practice of performing live-dead-live tests on voltmeters prior to working on an electrical circuit, components, devices and/or equipment.

Thus, as discussed herein, the embodiments of the present invention embrace a method for performing a live-dead-live test of a voltmeter. More particularly, the present invention relates to a method and an apparatus that confirms the voltmeter is operational before relying on it to perform work on an electrical circuit, electrical equipment, devices and/or components of an electrical circuit.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

1. A method for performing live-dead-live tests on voltmeters to verify that prior to working on an electrical circuit the voltmeter is operational.

2. An apparatus that will be powered by a battery and contain a “voltage selection switch” that will allow the user to chose an AC voltage output.

3. A n apparatus that will be powered by a battery and contain a “voltage selection switch” that will allow the user to chose a DC voltage output.

4. An apparatus that will contain LED indications that will illuminate when either AC or DC voltage is selected via the voltage selection switch. LED indication will:
a) Let the user know that the voltage output selected is operating and can be relied upon for the voltmeter operability confirmation and that
b) The battery power source of the apparatus is sufficient to power the apparatus and voltmeter display.

5. An apparatus that will have output jacks that will allow the insertion of a voltmeter probe, so that the probe and accompanying leads are also tested during the process of verifying the voltmeter is operable.

6. An apparatus that is portable and easily transported.

7. An apparatus that will enhance the “safe working practices” as described in the OSHA regulations “Selection and use of work practices 1910.333”, specifically paragraph 1910.333(b)(2)(iv)(B).
